(19) United States
(12) Patent Application Publication
(10) Pub. No.: US 2026/0304813 A1
(43) Pub. Date: Oct. 1, 2026

(54) THIN FILM TRANSISTOR SUBSTRATE AND MANUFACTURING METHOD THEREOF

(71) Applicant: InnoLux Corporation, Miao-Li County (TW)

(72) Inventors: Chin-Lung TING, Miao-Li County (TW); Wang-Cheng CHUNG, Miao-Li County (TW); Han-Tsung SU, Miao-Li County (TW); Jhe-Ciou JHU, Miao-Li County (TW); Te-Yi CHEN, Miao-Li County (TW)

(21) Appl. No.: 19/562,258

(22) Filed: Mar. 10, 2026

(30) Foreign Application Priority Data
Mar. 27, 2025 (CN) 202510371191.0

(51) Int. Cl. H10D 30/01; H10D 30/67

(52) U.S. Cl. CPC H10D 30/031; H10D 30/6755; H10D 30/6757

(57) ABSTRACT

A thin film transistor substrate includes a thin film transistor including a substrate, an oxide semiconductor layer, a gate structure, an oxidized metal layer, a source and a drain. The oxide semiconductor layer is disposed on the substrate and includes a first region and two second regions, and the current density of the two second regions is greater than the current density of the first region. The gate structure is correspondingly arranged on the first region of the oxide semiconductor layer. The oxidized metal layer is disposed on the oxide semiconductor layer and the gate structure, and contacts the oxide semiconductor layer and the gate structure. The source and the drain are arranged on the oxide semiconductor layer and contact the oxide semiconductor layer. The oxidized metal layer extends from one of the second regions through the gate structure to the other one of the second regions.

### CROSS-REFERENCE TO RELATED APPLICATIONS

This application claims the benefits of the Chinese Patent Application Serial Number 202510371191.0, filed on Mar. 27, 2025, the subject matter of which is incorporated herein by reference.

### BACKGROUND

### Field

The present disclosure relates to a thin film transistor substrate and a manufacturing method thereof.

### Description of Related Art

With the development of technology, displays have become ubiquitous electronic devices, in which transistors are used as components to control pixel switches.

In transistor manufacturing, the electrical properties of transistors can be adjusted through a doping process. However, the doping process and related equipment currently used in the industry are expensive and difficult to obtain at low cost, resulting in excessively high transistor production costs.

Therefore, it is desirable to provide a novel thin film transistor substrate and a manufacturing method thereof to improve the aforesaid problems.

### SUMMARY

The present disclosure provides a thin film transistor substrate comprising a plurality of thin film transistors, wherein one of the plurality of thin film transistors comprises: a substrate; an oxide semiconductor layer disposed on the substrate and comprising a first region and two second regions, wherein the first region is located between two second regions and current density of the two second regions is greater than current density of the first region; a gate structure correspondingly disposed on the first region of the oxide semiconductor layer; an oxidized metal layer disposed on the oxide semiconductor layer and the gate structure, and contacting the oxide semiconductor layer and the gate structure; and a source and a drain disposed on the oxide semiconductor layer and penetrating the oxidized metal layer to contact the oxide semiconductor layer, wherein the oxidized metal layer extends from one of the two second regions through the gate structure to the other one of the two second regions.

The present disclosure further provides a manufacturing method of a thin film transistor substrate, comprising the following steps: providing a substrate; forming a buffer layer on the substrate; forming an oxide semiconductor layer on the buffer layer, wherein the oxide semiconductor layer has a first region and two second regions adjacent to the first region; forming a gate structure on the first region of the oxide semiconductor layer; forming a metal layer on the oxide semiconductor layer and the gate structure, wherein the metal layer contacts the two second regions of the oxide semiconductor layer and the gate structure, and at least two gases are introduced during forming the metal layer; annealing the metal layer to form an oxidized metal layer and making current density of the two second regions of the oxide semiconductor layer greater than current density of the first region of the oxide semiconductor layer; and forming a source and a drain on the two second regions of the oxide semiconductor layer.

Other novel features of the disclosure will become more apparent from the following detailed description when taken in conjunction with the accompanying drawings.

### BRIEF DESCRIPTION OF DRAWINGS

FIG. 1 is a flow chart showing a manufacturing method of a thin film transistor substrate according to the present disclosure.

FIG. 2 shows a schematic view of a thin film transistor substrate according to one embodiment of the present disclosure.

FIG. 3 shows a schematic view of a thin film transistor substrate according to another embodiment of the present disclosure.

FIG. 4 shows a schematic view of a thin film transistor substrate according to another embodiment of the present disclosure.

FIG. 5 shows a schematic view of a thin film transistor substrate according to another embodiment of the present disclosure.

FIG. 6 shows a schematic view of a thin film transistor substrate according to another embodiment of the present disclosure.

FIG. 7 shows a schematic view of a thin film transistor substrate according to another embodiment of the present disclosure.

FIG. 8 shows a schematic view of a thin film transistor substrate according to another embodiment of the present disclosure.

### DETAILED DESCRIPTION

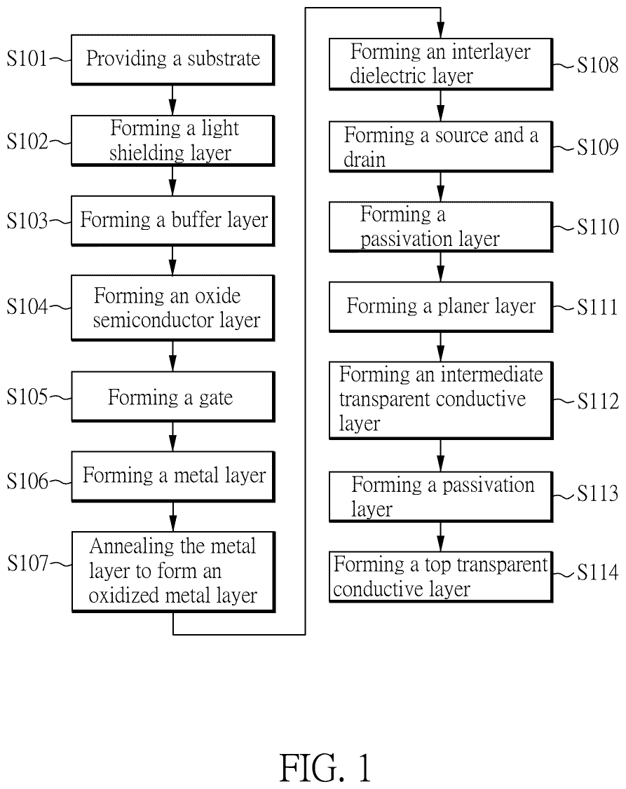

Please refer to FIG. 1, which is a flow chart showing a manufacturing method of a thin film transistor substrate according to the present disclosure. To clearly illustrate the process steps of this method, please refer to FIG. 2, which shows a schematic view of a thin film transistor substrate manufactured by the method of FIG. 1 according to one embodiment. Herein, the thin film transistor substrate comprises plural thin film transistors. For clarity of illustration, FIG. 2 shows one thin film transistor among a plurality of thin film transistors.

As shown in FIG. 2, the thin film transistor comprises a substrate 10, a light shielding layer 20, a buffer layer 30, an oxide semiconductor layer 40, a gate structure 50, an oxidized metal layer 60′, an interlayer dielectric layer 70, a source 81 and a drain 82. The light shielding layer 20 is disposed on the substrate 10. The buffer layer 30 is disposed on the light shielding layer 20 and the substrate 10 and may comprise a first buffer layer 31 and a second buffer layer 32, wherein a minimum thickness of the second buffer layer 32 may be greater than a minimum thickness of the first buffer layer 31. The oxide semiconductor layer 40 is disposed on the buffer layer 30, and the oxide semiconductor layer 40 has a first region 41 and two second regions 42 adjacent to the first region 41, wherein the first region 41 is located between the two second regions 42, and current density of the two second regions 42 is greater than current density of the first region 41. The gate structure 50 is correspondingly disposed on the first region 41 of the oxide semiconductor layer 40. The oxidized metal layer 60′ is disposed on the oxide semiconductor layer 40 and the gate structure 50 and contacts the oxide semiconductor layer 40 and the gate structure 50, wherein the oxidized metal layer 60′ extends from one of the two second regions 42 of the oxide semiconductor layer 40 through the gate structure to the other one of the two second regions 42. The source 81 and the drain 82 are disposed on the oxide semiconductor layer 40 and penetrating through the oxidized metal layer 60′ to contact the oxide semiconductor layer 40. In some embodiment, the oxidized metal layer 60′ may contact the substrate 10, but the present disclosure is not limited thereto. In further some embodiment, the oxidized metal layer 60′ may contact a side of the buffer layer 30, but the present disclosure is not limited thereto.

In one embodiment, in a normal direction Z of the substrate 10, the gate structure 50 and the first region 41 of the oxide semiconductor layer 40 are overlapped, and the gate structure 50 and the second regions 42 of the oxide semiconductor layer 40 are not overlapped. More specifically, for example, in the normal direction Z of the substrate 10, the gate metal layer 52 of the gate structure 50 and the first region 41 of the oxide semiconductor layer 40 may be overlapped, and the gate metal layer 52 of the gate structure 50 and the second regions 42 of the oxide semiconductor layer 40 may not be overlapped, but the present disclosure is not limited thereto. In one embodiment, a projection area of the gate structure 50 on the substrate 10 may be approximately equal to a projection area of the first region 41 of the oxide semiconductor layer 40 on the substrate 10, but the present disclosure is not limited thereto.

In the manufacturing method of the thin film transistor substrate, the step S101 is performed to provide a substrate 10. Next, the step S102 is performed to form a light shielding layer 20 on the substrate 10, wherein this step involves, for example, applying a metal layer, photolithography, etching, and photoresist stripping to form the light shielding layer 20. The material of the light shielding layer 20 may comprise, for example, but not limited to molybdenum, aluminum, molybdenum oxide, copper oxide, black photoresist, other suitable materials, or a combination thereof. Next, the step S103 is performed to form a buffer layer 30 disposed on the substrate 10, wherein this step involves, for example, forming the buffer layer 30 by coating, and the buffer layer 30 may comprise, for example, a first buffer layer 31 and a second buffer layer 32 disposed on the first buffer layer 31. The materials of the first buffer layer 31 and the second buffer layer 32 may respectively comprise silicon nitride (SiNx), silicon oxide (SiOx), silicon oxynitride, silicon carbonitride, aluminum oxide, organic materials, or a combination thereof, but the present disclosure is not limited thereto. In one embodiment, the material of the first buffer layer 31 may be, for example, silicon nitride (SiNx), the material of the second buffer layer 32 may be, for example, silicon oxide (SiOx), but this is only an example and not a limitation. The “coating process” may be, for example, dip coating, spin coating, roller coating, blade coating, spray coating, or a combination thereof, but the present disclosure is not limited thereto.

Next, the step S104 is performed to form an oxide semiconductor layer 40 on the buffer layer 30, wherein this step involves, for example, coating, lithography, etching and photoresist stripping to form the oxide semiconductor layer 40. The material of the oxide semiconductor layer 40 may comprise, for example, indium gallium zinc oxide (IGZO), indium gallium oxide (IGO), indium zinc oxide (IZO), Indium gallium zinc tin oxide (IGZTO) or other suitable metal oxides, but the present disclosure is not limited thereto. Then, the step S105 is performed to form a gate structure 50 on the first region 41 of the oxide semiconductor layer 40, wherein a top-gate insulation (TGI) layer 51 is formed on the first region 41 of the oxide semiconductor layer 40 by a coating process in this step, and the top-gate insulation layer 51 may comprise, for example, a first top-gate insulation layer 511 and a second top-gate insulation layer 512 disposed on the first top-gate insulation layer 511. The materials of the first top-gate insulation layer 511 and the second top-gate insulation layer 512 may respectively comprise silicon nitride (SiNx), silicon oxide (SiOx), silicon oxynitride, or a combination thereof, but the present disclosure is not limited thereto. In one embodiment, the material of the first top-gate insulation layer 511 is, for example, silicon oxide (SiOx), and the material of the second top-gate insulation layer 512 is, for example, silicon oxide (SiOx), but this is only an example and not a limitation. After forming the top-gate insulation layer 51, applying a metal layer, photolithography, etching, and photoresist stripping are performed to form a gate metal layer 52 disposed on the top-gate insulation layer 51.

Next, the step S106 is performed to form a metal layer on the oxide semiconductor layer 40 and the gate metal layer 52, and the metal layer contacts the second regions 42 of the oxide semiconductor layer 40 and the gate structure 50, wherein this step is, for example, forming a metal layer by sputtering, and at least two gases are introduced during forming the metal layer. In the present disclosure, the at least two gases may be, for example, helium, argon, oxygen or other suitable gases. In some embodiment, the gas introduced during forming the metal layer may be an inert gas, but the present disclosure is not limited thereto. In the present disclosure, a ratio of flow rates (sccm) of the two gases may be between 0.1 and 2 (0.1 ≤the ratio ≤2), for example, may be 0.2, 0.3, 0.35, 0.4, 0.5 or 1, but the present disclosure is not limited thereto. Next, the step S107 is performed to anneal the metal layer to form an oxidized metal layer 60′ disposed on the oxide semiconductor layer 40 and the gate metal layer 52, wherein the oxidized metal layer 60′ contacts the oxide semiconductor layer 40 and the gate metal layer 52, and the current density of the second regions 42 of the oxide semiconductor layer 40 is greater than the current density of the first region 41 of the oxide semiconductor layer 40. In the present disclosure, suitable annealing temperature may be between 200° C. and 600° C., for example, may be 250° C., 300° C., 400° C., 500° C. or 550° C., but the present disclosure is not limited thereto. In one embodiment, in the aforesaid steps S106, S107, the metal layer may be, for example, a thin aluminum film. In addition, during the sputtering process for forming the metal layer, for example, a mixed gas of helium (He) and argon (Ar) may be introduced to effectively reduce the film formation rate, thereby forming a thin metal layer with low roughness and/or high fineness. Then, annealing at an appropriate temperature is performed to oxidize the metal layer. The metal layer with higher activity will capture oxygen from the second regions 42 of the oxide semiconductor layer 40 below and contacting it, and the metal layer is completely oxidized into an oxidized metal layer which turns from a conductor into a non-conductor. After the annealing process, oxygen vacancies are formed in the second regions 42 of the oxide semiconductor layer 40 and the area contacting the oxide semiconductor layer, which produces an effect similar to doping (N+), causing the oxygen density on the surface of the second regions 42 of the oxide semiconductor layer 40 to be less than the oxygen density on the surface of the first region 41. Therefore, when the thin film transistor is powered, the current density of the second regions 42 of the oxide semiconductor layer 40 can be greater than that of the first region 41 of the oxide semiconductor layer 40. Furthermore, after annealing, the entire metal layer is oxidized to form an oxidized metal layer 60′, such as an aluminum oxide layer. This layer may be used as a diffusion barrier layer and helps negative biases of components affected by the process, thereby improving component performance. In one embodiment, the oxidized metal layer 60′ is fully covered, that is, the oxidized metal layer 60′ extends from the gate structure 50 to the oxide semiconductor layer 40, the buffer layer 30 and the substrate 10. A thickness of the oxidized metal layer 60′ is about 50 Å to 300 Å. In one embodiment, in a cross section, as shown in FIG. 2, the substrate 10 has an upper surface 101 and the buffer layer 30 has a side wall 301, wherein part of the oxidized metal layer 60′ may cover the side wall 301 of the buffer layer 30 and extend onto the upper surface 101 of the substrate 10. In other words, part of the oxidized metal layer 60′ may contact the side wall 301 of the buffer layer 30 and the upper surface 101 of the substrate 10, but the present disclosure is not limited thereto. The “upper surface 101 of the substrate 10” may refer to, for example, the surface of the substrate 10 adjacent to the oxide semiconductor layer 40. The “side wall 301 of the buffer layer 30” may refer to the side wall of the second buffer layer 32. However, the present disclosure is not limited thereto.

Next, the step S108 is performed to form an interlayer dielectric (ILD) layer 70 disposed on the oxidized metal layer 60′, wherein this step is performed, for example, by coating, photolithography, etching and photoresist stripping to form the interlayer dielectric layer 70, and the interlayer dielectric layer 70 has two vias 71 respectively for the source and drain disposed therein. Then, the step S109 is performed to form a source 81 and a drain 82 on the second regions 42 of the oxide semiconductor layer 40 and in the vias 71, thereby forming the thin film transistor substrate shown in FIG. 2. In this step, for example, the oxidized metal layer 60′ in the vias 71 is removed to expose the second regions 42 of the oxide semiconductor layer 40 in the vias 71, then the source 81 and the drain 82 contacting the second regions 42 of the oxide semiconductor layer 40 are formed in the vias 71 by coating a metal layer, photolithography, etching and photoresist stripping. That is, as shown in FIG. 2, the source 81 and the drain 82 are disposed on the interlayer dielectric layer 70 and the oxide semiconductor layer 40 and penetrate through the oxidized metal layer 60′ to contact the second regions 42 of the oxide semiconductor layer 40. Herein, the oxidized metal layer 60′ extends from one of the two second regions 42 (for example, the second region 42a) through the gate structure 50 to the other of the two second regions 42 (for example, the second region 42b). More specifically, as shown in FIG. 2, the oxidized metal layer 60′ extends from the upper surface of one second region 42a through the upper surface of the gate structure 50 to the upper surface of the other second region 42b, and the source 81 and the drain 82 contact the second regions 42 (including the second region 42a and the second region 42b) of the oxide semiconductor layer 40 through the vias 71 of the interlayer dielectric layer 70 and the vias 61 of the oxidized metal layer 60′, wherein the vias 71 and the vias 61 are connected.

Next, the steps S110, S111, S112, S113, S114 may be selectively continuously performed to form a passivation layer (PV layer), a planer layer (PFA layer), an intermediate transparent conductive layer (MIT layer), a passivation layer (PV layer) and a top transparent conductive layer (TIT layer). The materials of the passivation layer and the planer layer may respectively comprise silicon oxide, silicon oxynitride, silicon nitride, aluminum oxide, resin, polymer, photoresist or a combination thereof, but the present disclosure is not limited thereto. The materials of the intermediate transparent conductive layer and the top transparent conductive layer may respectively comprise indium tin oxide (ITO), indium zinc oxide (IZO), indium tin zinc oxide (ITZO), indium gallium zinc oxide (IGZO) or aluminum zinc oxide (AZO), but the present disclosure is not limited thereto. Since these steps S110 to S114 may be selectively performed, the thin film transistor substrate shown in FIG. 2 does not comprise the above layers. In addition, the process sequence of the steps S101 to S114 may be appropriately adjusted according to the needs, and steps S101 to S114 may also be increased and/or decreased depending on the structure, which will not be described in detail here.

Furthermore, since the aforementioned step S106 is to form the metal layer by introducing a mixed gas (for example, containing helium and oxygen) during the sputtering process, the metal layer can be formed into a uniform metal film, such as but not limited to an aluminum thin film. Therefore, after the metal layer is annealed in the step S107 and oxidized to become the oxidized metal layer 60′, it can have low roughness and/or high density. In one embodiment, the roughness of the oxidized metal layer 60′ is less than the roughness of the buffer layer 30, the roughness of the oxidized metal layer 60′ is less than the roughness of the interlayer dielectric layer 70, and/or the roughness of the oxidized metal layer 60′ is less than the roughness of the top-gate insulation layer 51, but the present disclosure is not limited thereto. In one embodiment, the density of the oxidized metal layer 60′ is greater than the density of the buffer layer 30, and the density of the oxidized metal layer 60′ is greater than the density of the interlayer dielectric layer 70, but the present disclosure is not limited thereto. The “roughness of a component” refers to, for example, the roughness of the surface of the component, which may be determined by observing the surface roughness of the component using a scanning electron microscope (SEM), or by calculating the average roughness (Ra) of a sample per unit length using an SEM or transmission electron microscope (TEM). The “density of a component” may be measured by observing the size and number of pores between atoms, molecules or polymers that form the component under a fixed area through the cross section of the component. For a fixed area, the more pores there are and/or the larger the pores, the lower the density. Conversely, the fewer pores there are and/or the smaller the pores, the higher the density. The density of a component may be determined through images or data generated by instruments such as SEM, transmission electron microscope (TEM), and energy dispersive X-ray spectroscopy (EDX), but the present disclosure is not limited thereto.

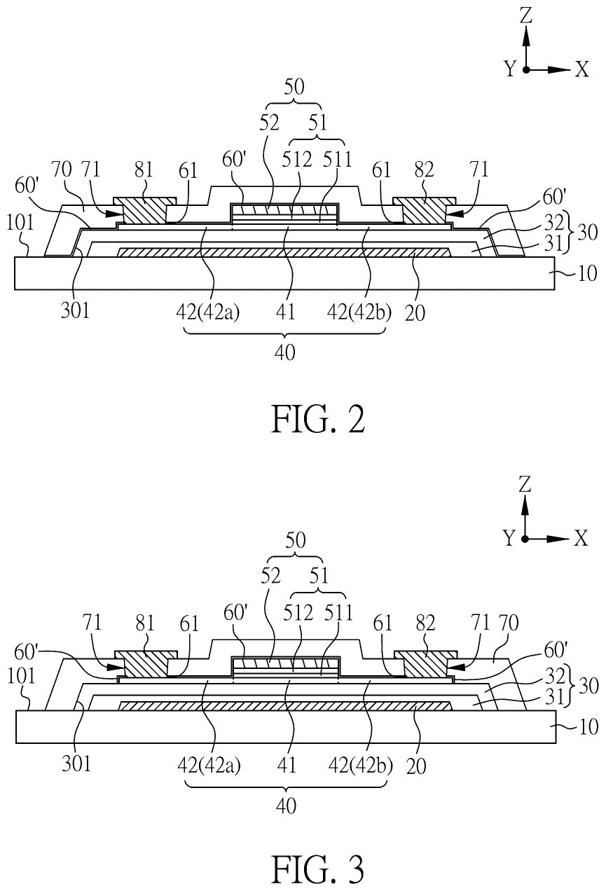

FIG. 3 shows a schematic view of a thin film transistor substrate manufactured by the process shown in FIG. 1 according to another embodiment of the present disclosure. The present embodiment is similar to that shown in FIG. 2 except for the following differences.

In one embodiment, as shown in FIG. 3, the oxidized metal layer 60′ partially covers, that is, the oxidized metal layer 60′ covers the oxide semiconductor layer 40. The thickness of the oxidized metal layer 60′ is about 100 Å to 300 Å. More specifically, in one cross section, as shown in FIG. 3, the oxidized metal layer 60′ does not contact the side wall 301 of the buffer layer 30, and the oxidized metal layer 60′ does not contact the upper surface 101 of the substrate 10. That is, the oxidized metal layer 60′ does not cover the side wall 301 of the buffer layer 30, but the present disclosure is not limited thereto.

In addition, other features of the present embodiment may refer to the description of Embodiment of FIG. 2, which will not be repeated.

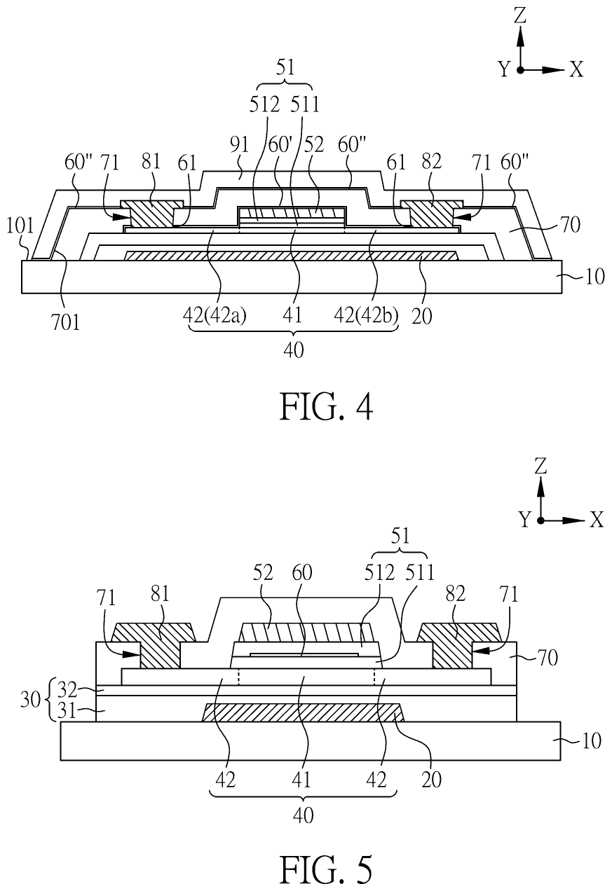

FIG. 4 shows a schematic view of a thin film transistor substrate manufactured by the process shown in FIG. 1 according to another embodiment of the present disclosure. The manufacturing method of the thin film transistor substrate of the present embodiment can be obtained by adjusting the process of FIG. 1 based on the structure of the thin film transistor substrate of FIG. 4. The present embodiment is similar to that shown in FIG. 3 except for the following differences.

In one embodiment, as shown in FIG. 4, after performing the step S109, the steps S106, S107 may be performed again to form another oxidized metal layer 60″ on the interlayer dielectric layer 70. Then, the step S110 is performed to form a passivation layer 91 on another oxidized metal layer 60″, the source 81 and the drain 82. In one embodiment, during the sputtering process for forming another oxidized metal layer 60″, at least one gas such as helium or argon may be introduced. More specifically, another oxidized metal layer 60″ is disposed between the interlayer dielectric layer 70 and the passivation layer 91 for providing insulation. In one cross section, as shown in FIG. 4, the interlayer dielectric layer 70 has a side wall 701, and another oxidized metal layer 60″ may cover the side wall 701 of the interlayer dielectric layer 70 and extend onto the upper surface 101 of the substrate 10. In other words, part of the oxidized metal layer 60″ may contact the side wall 701 of the interlayer dielectric layer 70 and the upper surface 101 of the substrate 10, but the present disclosure is not limited thereto. In one embodiment, the density of the oxidized metal layer 60′ is greater than or equal to the density of another oxidized metal layer 60″, and the surface roughness of the oxidized metal layer 60′ is greater than the surface roughness of another oxidized metal layer 60″. In one embodiment, the density of the oxidized metal layer 60′ may be greater than the density of the passivation layer 91. In one embodiment, the surface roughness of the oxidized metal layer 60′ may be less than the surface roughness of the passivation layer 91. In some embodiment, during the sputtering process, the plating rate for forming the oxidized metal layer 60″ may be greater than or equal to the plating rate for forming the oxidized metal layer 60′, but the present disclosure is not limited thereto. In further some embodiment, the thickness of the oxidized metal layer 60″ may be greater than or equal to the thickness of the oxidized metal layer 60′, but the present disclosure is not limited thereto.

In addition, other features of the present embodiment can be referred to the description of Embodiments shown in FIG. 2 and FIG. 3, so no further details are given. In other embodiments, the thin film transistor substrate may also be disposed with the oxidized metal layer 60″ but not disposed with the oxidized metal layer 60′, which will not be described in detail here.

FIG. 5 shows a schematic view of a thin film transistor substrate manufactured according to another embodiment of the present disclosure. The manufacturing method of the thin film transistor substrate of the present embodiment can be obtained by adjusting the process of FIG. 1 based on the structure of the thin film transistor substrate of FIG. 5.

In one embodiment, as shown in FIG. 5, after performing the step S101 to the step S104, the step S105 and the step S106 are performed. More specifically, in the step S105 and the step S106, for example, the first top-gate insulation layer 511 is formed on the oxide semiconductor layer 40, and then a metal layer 60 is formed on the first top-gate insulation layer 511. Next, the second top-gate insulation layer 512 is formed on the metal layer 60, followed by forming the gate metal layer 52 on the second top-gate insulation layer 512. In the present disclosure, the metal layer 60 may be formed by sputtering, photolithography, etching and photoresist stripping. During the sputtering process, at least two gases are introduced to effectively reduce the film formation rate, so that the metal layer 60 is formed into a uniform metal film. The thickness of the metal layer 60 may be greater than 300 Å. The metal layer 60 may comprise, but not limited to, aluminum, magnesium, zinc, nickel, tin, lead or a combination thereof. In the present disclosure, the gas may be, for example, at least two of helium and argon. In the present disclosure, the ratio of the flow rates (sccm) of the two gases may be between 0.1 and 2, and for example, between 0.2 and 2 or between 0.35 and 2, but the present disclosure is not limited thereto. In one embodiment, the oxide semiconductor layer 40 may comprise a first region 41 and two second regions 42 adjacent to the first region 41, wherein the first region 41 is located between two second regions 42. The first region 41 refers to, for example, the overlapping region of the gate metal layer 52 and the oxide semiconductor layer 40 in the normal direction Z of the substrate 10, and the second region 42 refers to the region outside the first region 41 of the oxide semiconductor layer 40. In one embodiment, in the normal direction Z of the substrate 10, the metal layer 60 and the first region 41 of the oxide semiconductor layer 40 may be overlapped. In one embodiment, the first top-gate insulation layer 511 and the second top-gate insulation layer 512 may form a top-gate insulation layer 51, so the metal layer 60 may be embedded into the top-gate insulation layer 51.

Next, the step S108 is performed. That is, an interlayer dielectric layer 70 is formed on the gate metal layer 52 and the oxide semiconductor layer 40. The interlayer dielectric layer 70 has two vias 71 respectively for disposing the source 81 and the drain 82. Then, the step S109 is performed. That is, the source 81 and the drain 82 are formed on the interlayer dielectric layer 70 and in the vias 71, to form the thin film transistor substrate shown in FIG. 5. In one embodiment, the lamination of the metal layer 60, the oxide semiconductor layer 40 and the light shielding layer 20 may constitute a memristor structure, but the present disclosure is not limited thereto.

In the present embodiment, the metal layer 60 with higher activity will be partially oxidized after the annealing process, and the conductivity thereof is maintained. In further some embodiment, the thickness of the metal layer 60 with higher activity may be greater than 300 Å, but the present disclosure is not limited thereto. In further some embodiment, the annealing process may not be performed on the metal layer 60 according to the design requirement, but the present disclosure is not limited thereto. The partially oxidized metal layer may be a floating electrode. When a first voltage is applied to the gate metal layer 52 to transfer electrons in the partially oxidized metal layer to the oxide semiconductor layer 40, the memristor structure is in the first configuration, and the threshold voltage of the transistor is low. When a second voltage is applied to the gate metal layer 52 to transfer electrons in the oxide semiconductor layer 40 to the partially oxidized metal layer, the memristor structure is in the second configuration, and the threshold voltage of the transistor is high. When the memristor structure is in the first configuration, if the second voltage is not provided to change the configuration, the transistor state remains in the first configuration, that is, the lower threshold voltage, and vice versa. Thus, the configuration of the partially oxidized metal layer can give the transistor a memory function.

In addition, other features of the present embodiment may refer to the description of the embodiment of FIG. 2, so no further details are given.

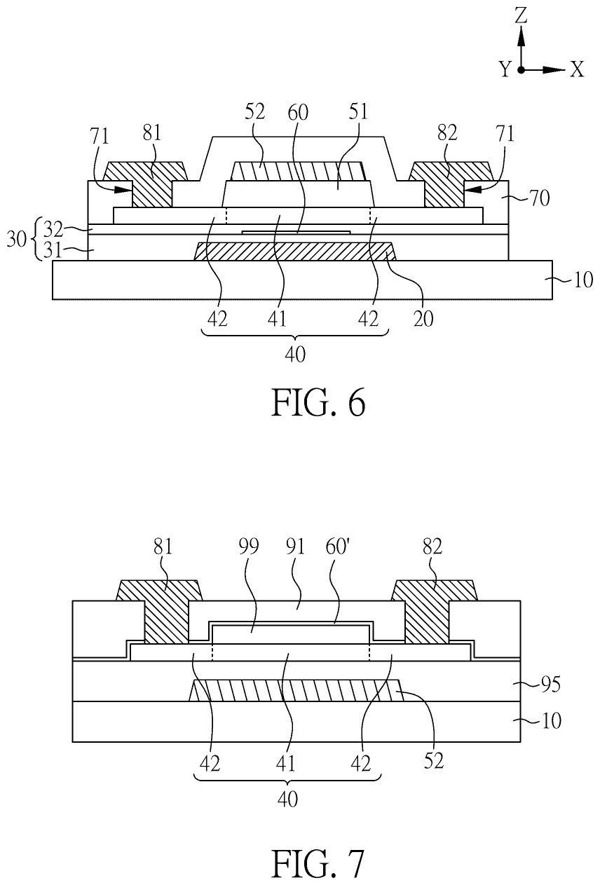

FIG. 6 shows a schematic view of a thin film transistor substrate manufactured according to another embodiment of the present disclosure. The manufacturing method of the thin film transistor substrate of the present embodiment can be obtained by adjusting the process of FIG. 1 based on the structure of the thin film transistor substrate of FIG. 6. The present embodiment is similar to that of FIG. 5 except for the following differences.

In one embodiment, as shown in FIG. 6, after performing the step S101 to the step S102, the step S103 and the step S106 are performed. More specifically, in the step S103 and the step S106, for example, the first buffer layer 31 is formed on the light shielding layer 20, followed by forming a metal layer 60 on the first buffer layer 31, and then a second buffer layer 32 is formed on the metal layer 60. In the present disclosure, the metal layer 60 may be formed by sputtering, photolithography, etching and photoresist stripping. During the sputtering process, at least two gases are introduced to effectively reduce the film formation rate, so that the metal layer 60 is formed into a uniform metal film. The thickness of the metal layer 60 may be greater than 300 Å. The metal layer 60 may comprise, but not limited to, aluminum, magnesium, zinc, nickel, tin, lead or a combination thereof. In the present disclosure, the gas may be, for example, at least two gases of helium and argon. In the present disclosure, the ratio of the flow rates (sccm) of the two gases may be between 0.1 and 2, for example, between 0.2 and 2 or between 0.35 and 2, but the present disclosure is not limited thereto. In one embodiment, in the normal direction Z of the substrate 10, the metal layer 60 and the light shielding layer 20 may be overlapped. In one embodiment, the first buffer layer 31 and the second buffer layer 32 may form a buffer layer 30, and the metal layer 60 may be embedded into the buffer layer 30.

Next, the step S104 and the step S105 are performed. More specifically, for example, an oxide semiconductor layer 40 is first formed on the buffer layer 30, a top-gate insulation layer 51 is formed on the oxide semiconductor layer 40, and a gate metal layer 52 is formed on the top-gate insulation layer 51. In one embodiment, the oxide semiconductor layer 40 may comprise a first region 41 and two second regions 42 adjacent to the first region 41, wherein the first region 41 is located between the two second regions 42. The first region 41 refers to, for example, the overlapping region of the gate metal layer 52 and the oxide semiconductor layer 40 in the normal direction Z of the substrate 10, and the second region 42 refers to, for example, the region outside the first region 41 of the oxide semiconductor layer 40. In one embodiment, in the normal direction Z of the substrate 10, the top-gate insulation layer 51 and the first region 41 of the oxide semiconductor layer 40 may be overlapped. In one embodiment, in the normal direction Z of the substrate 10, the metal layer 60 and the first region 41 of the oxide semiconductor layer 40 may be overlapped.

Next, the steps S108, S109 are performed to form the thin film transistor substrate shown in FIG. 6. In one embodiment, the lamination of the gate metal layer 52, the oxide semiconductor layer 40 and the metal layer 60 may form a memristor structure, but the present disclosure is not limited thereto.

In addition, other features of the present embodiment may refer to the description of the embodiment of FIG. 5, so no further details are given.

FIG. 7 shows a schematic view of a thin film transistor substrate manufactured according to another embodiment of the present disclosure. The manufacturing method of the thin film transistor substrate of the present embodiment can be obtained by adjusting the process of FIG. 1 based on the structure of the thin film transistor substrate of FIG. 7. The thin film transistor substrate of the present embodiment comprises a substrate 10, a gate metal layer 52, a gate insulation layer 95, an oxide semiconductor layer 40, an etching stopping layer 99, an oxidized metal layer 60′, a passivation layer 91, a source 81 and a drain 82. The gate metal layer 52 is disposed on the substrate 10. The gate insulation layer 95 is disposed on the gate metal layer 52 and the substrate 10. The oxide semiconductor layer 40 is disposed on the gate insulation layer 95, and the oxide semiconductor layer 40 has a first region 41 and two second regions 42 adjacent to the first region 41. The gate metal layer 52 is correspondingly disposed under the first region 41 of the oxide semiconductor layer 40, and the first region 41 is located between the two second regions 42. The current density of the two second regions 42 is greater than the current density of the first region 41. The etching stopping layer 99 is correspondingly disposed on the first region 41 of the oxide semiconductor layer 40. The oxidized metal layer 60′ is disposed on the oxide semiconductor layer 40 and the etching stopping layer 99 and contacts the oxide semiconductor layer 40. The oxidized metal layer 60′ extends from one of the two second regions 42 of the oxide semiconductor layer 40 through the etching stopping layer 99 to the other one of the two second regions 42. The source 81 and the drain 82 are disposed on the oxide semiconductor layer 40 and penetrate the oxidized metal layer 60′ to contact the oxide semiconductor layer 40.

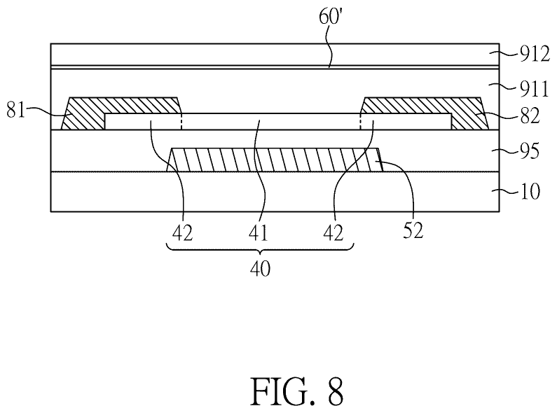

FIG. 8 shows a schematic view of a thin film transistor substrate manufactured according to another embodiment of the present disclosure. The manufacturing method of the thin film transistor substrate of the present embodiment can be obtained by adjusting the process of FIG. 1 based on the structure of the thin film transistor substrate of FIG. 8. The thin film transistor substrate of the present embodiment comprises a substrate 10, a gate metal layer 52, a gate insulation layer 95, an oxide semiconductor layer 40, a first passivation layer 911, a second passivation layer 912, an oxidized metal layer 60′, a source 81 and a drain 82. The gate metal layer 52 is disposed on the substrate 10. The gate insulation layer 95 is disposed on the gate metal layer 52 and the substrate 10. The oxide semiconductor layer 40 is disposed on the gate insulation layer 95, and the oxide semiconductor layer 40 may comprise a first region 41 and two second regions 42 adjacent to the first region 41. The gate metal layer 52 is correspondingly disposed under the first region 41 of the oxide semiconductor layer 40, and the first region 41 is located between the two second regions 42. The source 81 and the drain 82 are disposed on the gate insulation layer 95 and the oxide semiconductor layer 40 and respectively contact the two second regions 42 of the oxide semiconductor layer 40. The first passivation layer 911 is disposed on the gate insulation layer 95, the oxide semiconductor layer 40, the source 81 and the drain 82. The oxidized metal layer 60′ is disposed on the first passivation layer 911. The second passivation layer 912 is disposed on the oxidized metal layer 60′.

From the above description, it can be seen that the present disclosure can effectively reduce the film formation rate by introducing at least two gases to perform the sputtering process during the process of forming the metal layer. Therefore, a more uniform active metal layer can be obtained by forming the layer in this way. In addition, after forming the thin metal layer, it can be selectively annealed at an appropriate temperature to allow the active metal layer to capture oxygen from the oxide semiconductor layer and naturally form an N+ doped area. Furthermore, the active metal layer is also entirely oxidized after annealing, forming a diffusion barrier layer that helps protect the device from negative bias due to process influences.

1. A thin film transistor substrate, comprising a plurality of thin film transistors, wherein one of the plurality of thin film transistors comprises:
a substrate;
an oxide semiconductor layer disposed on the substrate and comprising a first region and two second regions, wherein the first region is located between two second regions and current density of the two second regions is greater than current density of the first region;
a gate structure correspondingly disposed on the first region of the oxide semiconductor layer;
an oxidized metal layer disposed on the oxide semiconductor layer and the gate structure, and contacting the oxide semiconductor layer and the gate structure; and
a source and a drain disposed on the oxide semiconductor layer and penetrating the oxidized metal layer to contact the oxide semiconductor layer,
wherein the oxidized metal layer extends from one of the two second regions through the gate structure to the other one of the two second regions.

2. The thin film transistor substrate of claim 1, wherein the one of the plurality of thin film transistors further comprises a buffer layer disposed on the substrate, and the oxide semiconductor layer is formed on the buffer layer, wherein a roughness of the oxidized metal layer is less than a roughness of the buffer layer, and a density of the oxidized metal layer is greater than a density of the buffer layer.

3. The thin film transistor substrate of claim 2, wherein the oxidized metal layer contacts a side wall of the buffer layer and an upper surface of the substrate.

4. The thin film transistor substrate of claim 1, wherein the one of the plurality of thin film transistors further comprises an interlayer dielectric layer disposed on the oxidized metal layer, and the interlayer dielectric layer has two vias with the source and the drain respectively disposed therein, wherein a roughness of the oxidized metal layer is less than a roughness of the interlayer dielectric layer, and a density of the oxidized metal layer is greater than a density of the interlayer dielectric layer.

5. The thin film transistor substrate of claim 4, wherein the one of the plurality of thin film transistors further comprises another oxidized metal layer disposed on the interlayer dielectric layer, wherein the roughness of the oxidized metal layer is greater than a roughness of the another oxidized metal layer, and the density of the oxidized metal layer is greater than or equal to a density of the another oxidized metal layer.

6. The thin film transistor substrate of claim 5, wherein a thickness of the another oxidized metal layer is greater than or equal to the thickness of the oxidized metal layer.

7. The thin film transistor substrate of claim 1, wherein the gate structure comprises a top-gate insulation layer and a gate metal layer disposed on the top-gate insulation layer, and a roughness of the oxidized metal layer is less than a roughness of the top-gate insulation layer.

8. The thin film transistor substrate of claim 1, wherein an oxygen density on surfaces of the two second regions of the oxide semiconductor layer is less than an oxygen density on a surface of the first region.

9. The thin film transistor substrate of claim 1, wherein a thickness of the oxidized metal layer is 50 Å to 300 Å.

10. The thin film transistor substrate of claim 1, wherein the oxidized metal layer is an aluminum oxide layer.

11. A manufacturing method of a thin film transistor substrate, comprising the following steps:
providing a substrate;
forming a buffer layer on the substrate;
forming an oxide semiconductor layer on the buffer layer, wherein the oxide semiconductor layer has a first region and two second regions adjacent to the first region;
forming a gate structure on the first region of the oxide semiconductor layer;
forming a metal layer on the oxide semiconductor layer and the gate structure, wherein the metal layer contacts the two second regions of the oxide semiconductor layer, and at least two gases are introduced during forming the metal layer;
annealing the metal layer to form an oxidized metal layer and making current density of the two second regions of the oxide semiconductor layer greater than current density of the first region of the oxide semiconductor layer; and
forming a source and a drain on the two second regions of the oxide semiconductor layer.

12. The manufacturing method of claim 11, wherein the metal layer is formed on the oxide semiconductor layer and the gate structure by a sputtering process and contacts the second regions of the oxide semiconductor layer and the gate structure.

13. The manufacturing method of claim 11, wherein the at least two gases include at least two of helium and argon.

14. The manufacturing method of claim 13, wherein the at least two gases are helium and argon, and a ratio of a flow rate of helium to a flow rate of argon is between 0.1 and 2.

15. The manufacturing method of claim 11, wherein a roughness of the oxidized metal layer is less than a roughness of the buffer layer, and a density of the oxidized metal layer is greater than a density of the buffer layer.

16. The manufacturing method of claim 11, wherein an oxygen density on surfaces of the two second regions of the oxide semiconductor layer is less than an oxygen density on a surface of the first region.

17. The manufacturing method of claim 11, further comprising a step of:
forming an interlayer dielectric layer on the oxidized metal layer before the step of forming the source and the drain, wherein the interlayer dielectric layer has two vias with the source and the drain respectively disposed therein.

18. The manufacturing method of claim 11, wherein the oxidized metal layer extends from one of the two second regions through the gate structure to the other one of the two second regions.

19. The manufacturing method of claim 11, wherein a thickness of the oxidized metal layer is 50 Å to 300 Å.

20. The manufacturing method of claim 11, wherein the oxidized metal layer is an aluminum oxide layer.
